(19) United States
(12) Patent Application Publication
(10) Pub. No.: US 2009/0134442 A1
(43) Pub. Date: May 28, 2009

(54) RECESSED CHANNEL DEVICE AND METHOD THEREOF

(75) Inventors: Shian-Jyh Lin, Yonghe City (TW); Yuan Tsung Chang, Taipei City (TW); Shun-Fu Chen, Xindian City (TW); Chung-Tze Lin, Ruifang Town (TW); Chung-Yuan Lee, Taoyuan City (TW); Tse Chuan Kuo, Taipei City (TW)

Correspondence Address: INGRASSIA FISHER & LORENZ, P.C., 7010 E. COCHISE ROAD, SCOTTSDALE, AZ, 85253, US

(73) Assignee: NANYA TECHNOLOGY CORP., Taoyuan (TW)

(21) Appl. No.: 12/103,590

(22) Filed: Apr. 15, 2008

(30) Foreign Application Priority Data
Nov. 27, 2007 (TW) 96145005

(51) Int. Cl. H01L 27/108; H01L 21/8242

(52) U.S. Cl. 257/301; 438/243; 257/E21.655; 257/E27.091

(57) ABSTRACT

A method for forming a recessed channel device includes providing a substrate with a plurality of trench capacitors formed therein, each of the trench capacitors including a plug protruding above the substrate; forming a spacer on each of the plugs; forming a plurality of trench isolations along a first direction in the substrate adjacent to the trench capacitors so as to define an active area exposing the substrate; removing a portion of the substrate by using the spacers and the trench isolations as a mask to form a recessed channel; and trimming the recessed channel so that a surface profile of the recessed channel presents a three-dimensional shape. A recessed channel device with a rounded channel profile is also provided.

### CROSS REFERENCE TO RELATED APPLICATION

This application claims the right of priority based on Taiwan Patent Application No. 096145005 entitled “Recessed Channel Device and method thereof”, filed on Nov. 27, 2007, which is incorporated herein by reference and assigned to the assignee herein.

### FIELD OF THE INVENTION

The present invention relates to a semiconductor device and a method thereof, and more particularly, relates to a recessed channel device with a three-dimensional channel profile and a method thereof.

### BACKGROUND OF THE INVENTION

As the integration density of semiconductor devices increases and the size of field effect transistor (FET) continuously scales down, the short channel effect becomes a severe issue due to the decrease of channel length. A recessed channel technique is one of the means to address the issue. A recessed channel transistor provides a nonlinear channel, such as a U shape channel, so that the effective channel is significantly increased compared with a conventional planar transistor. Therefore, the recessed channel device is one of the preferred options when the device scales down.

As the size of transistor shrinks to sub-60 nanometers, a conventional recessed channel device may be the solution to the short channel effect and the junction leakage, but needs to face the issue of too small driving current due to the high threshold voltage caused by the longer channel. Therefore, how to increase the channel area at a limited channel length is an important issue, and FinFET device with multiple gates becomes another options. FinFET device provides a three-dimensional channel, which has the advantages of reducing the leakage current from the substrate, obtaining a higher driving current, and inhibiting the short channel effect.

In order to further effectively utilize the substrate area, integrating the recessed channel transistor with a trench capacitor becomes an advancing technique. However, the integration of the recessed channel transistor with the trench capacitor complicates the manufacture processes and significantly reduces the process window. That is, the alignment of layers is a critical factor that affects the performance of the semiconductor device. Particularly, when the recessed channel is defined by lithography, a slight misalignment may cause the device to fail.

Therefore, there is a desire to provide a method for effectively integrating the recessed channel device with the trench capacitor to form a memory device with a rounded channel profile as the fin type gate.

### SUMMARY OF THE INVENTION

In view of the prior art drawbacks, one aspect of the present invention is to provide a method for forming a recessed channel device to enhance the driving current.

Another aspect of the present invention is to provide a method for forming a recessed channel device, which integrates the trench capacitor and uses the self-align technique to define the recessed channel so that the required photomasks for a memory device are minimized.

Another further aspect of the present invention is to provide a method for forming a recessed channel device, which forms a rounded recessed channel to increase the channel area resulting in the improvement of the short channel effect.

In one embodiment, the present invention provides a method for forming a recessed channel device including providing a substrate with a plurality of trench capacitors formed therein, each of the trench capacitors including a plug protruding above the substrate; forming a spacer on each of the plugs; forming a plurality of trench isolations along a first direction in the substrate adjacent to the trench capacitors so as to define an active area exposing the substrate; removing a portion of the substrate by using the spacers and the trench isolations as a mask to form a recessed channel; and trimming the recessed channel so that a surface profile of the recessed channel presents a three-dimensional shape.

In one exemplary embodiment, the step of providing the substrate includes forming a hardmask with multiple openings arranged in array on a substrate and each of the openings exposing a trench capacitor in the substrate; forming the plug in each of the openings and adjacent to the hard mask; and removing the hardmask. Prior to the step of forming the spacer, the method further includes forming a dielectric liner on the substrate. After the step of forming the spacer, the method further includes forming a filling layer filling between the spacers. The step of forming the filling layer includes blanket-forming a polysilicon layer to fill a space between the spacers; and chemical mechanical polishing the polysilicon layer to expose the plugs.

The step of forming the trench isolations includes using lithography technique to define a pattern of parallel trench isolations on the substrate; removing portions of the filling layer, the plugs, the trench capacitors, and the substrate to form a plurality of parallel trench openings by using the pattern of parallel trench isolations as a mask; and filling the trench openings with a dielectric material.

In one embodiment, the step of trimming the recessed channel includes reducing the spacers and the trench isolations; and etching a portion of the recessed channel so that the recessed channel has a rounded channel profile. The method further includes steps of forming a gate dielectric layer, a gate conductor, source/drain regions, an isolation, a plug conductor, a control gate, and a dielectric spacer.

Another aspect of the present invention is to provide a recessed channel device with a rounded recessed channel.

In one embodiment, a recessed channel device includes a substrate with at least two trench capacitors formed therein; and a recessed channel in the substrate between the two trench capacitors, wherein the recessed channel has a rounded channel profile.

The recessed channel device further includes a plurality of trench isolations along a first direction in the substrate adjacent to the trench capacitors to define an active area. In one exemplary embodiment, the recessed channel device further includes a gate dielectric layer covering the recessed channel, a gate conductor on the gate dielectric layer, source/drain regions in the substrate adjacent to the recessed channel, an isolation adjacent to the source/drain regions, a plug conductor adjacent to the isolation, and a control gate.

### BRIEF DESCRIPTION OF THE DRAWINGS

FIG. 1A to FIG. 8 illustrates schematic views of various stages in accordance with one embodiment of the present invention, wherein FIG. 1B and FIG. 4B are respective cross-sectional views along the B-B direction of FIG. 1A and FIG. 4A, and FIG. 6 is a schematic three-dimensional view of a portion of the recessed channel in FIG. 5.

### DETAILED DESCRIPTION OF THE INVENTION

The present invention discloses a recessed channel device and a method thereof, which integrates the trench capacitor and uses the self-align technique to define the recessed channel so that the required photomasks for a memory device are minimized. The present invention may best be understood by reference to the following description in conjunction with the accompanying drawings, in which similar reference numbers represent similar elements. Any devices, components, materials, and steps described in the embodiments are only for illustration and not intended to limit the scope of the present invention.

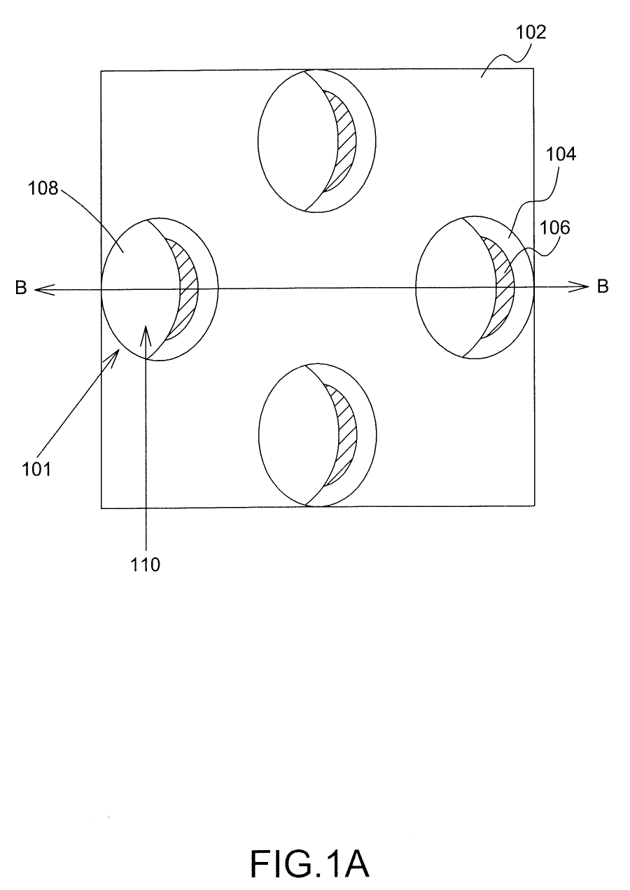

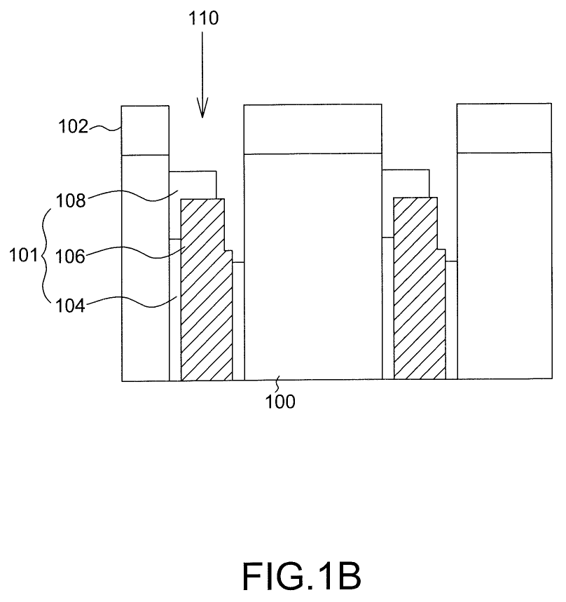

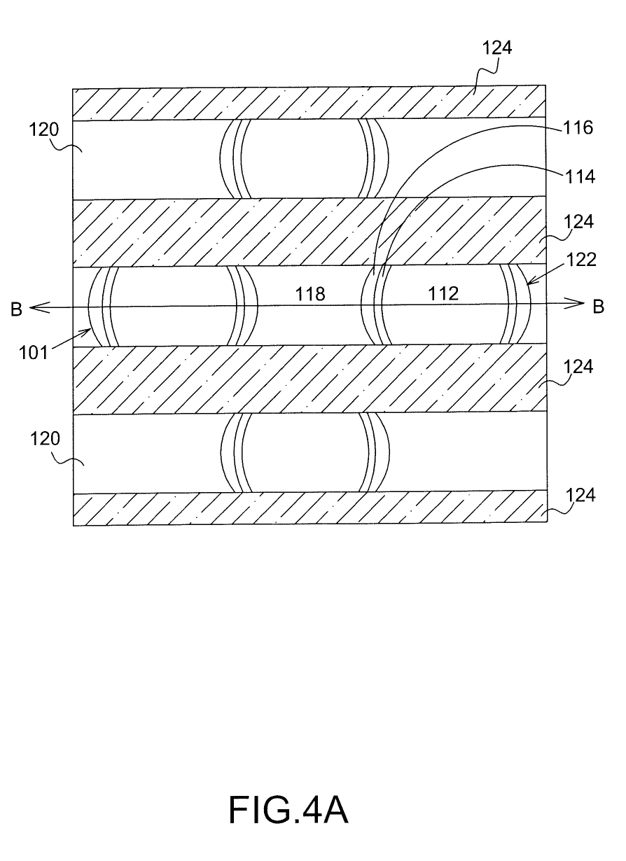

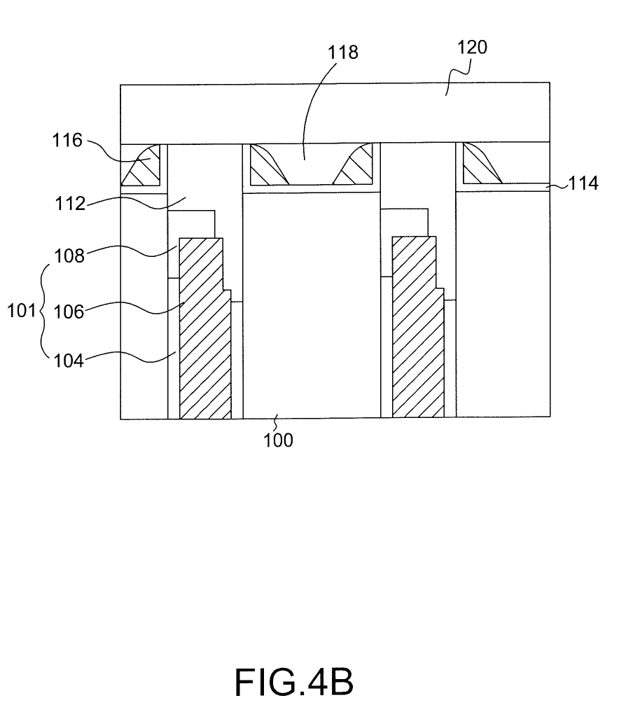

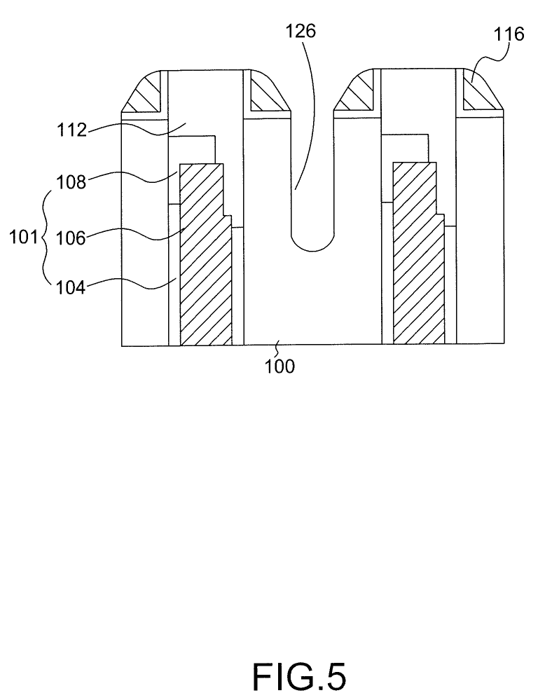

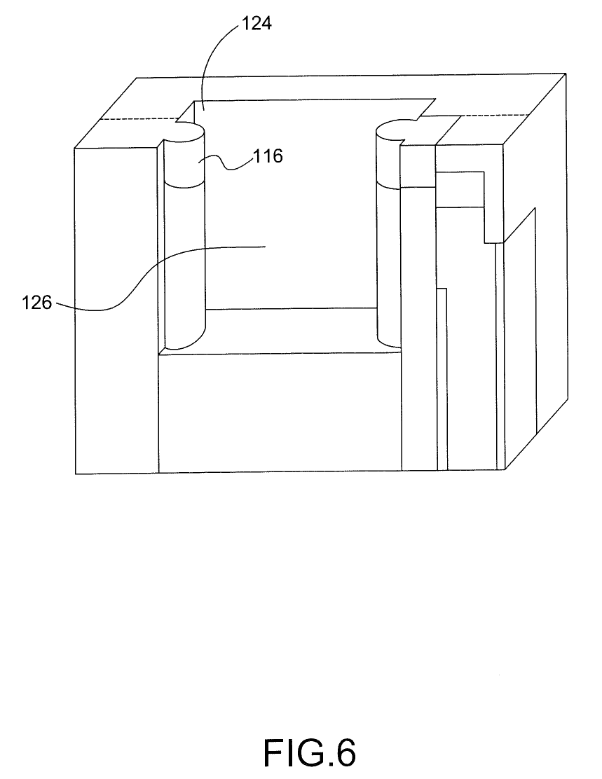

FIG. 1A to FIG. 8 illustrates schematic views of various stages of forming a recessed channel device in accordance with one embodiment of the present invention. FIG. 1B and FIG. 4B are respective cross-sectional views along the B-B direction of FIG. 1A and FIG. 4A, and FIG. 6 is a schematic three-dimensional view of a portion of the recessed channel shown in FIG. 5.

In one embodiment, the present invention provides a method for forming a recessed channel device, which is exemplarily illustrated by way of a memory device with a trench capacitor and a recessed channel transistor. It is noted that the present invention is applicable to any semiconductor device in need of a recessed channel. With reference to FIG. 1A and FIG. 1B, a substrate structure is provided, which includes a hardmask 102 on a substrate 100. The hardmask 102 has a plurality of openings 110 arranged in array, and each of the openings 110 exposes a trench capacitor 101 formed in the substrate 100. In one exemplary embodiment, the trench capacitor 101 formed in the substrate 100 includes a single-sided buried strap trench capacitor. For example, the substrate 100 may be any suitable semiconductor substrate, which includes but not limited to a silicon substrate, a semiconductor-on-insulator (SOI) substrate, or a compound semiconductor substrate. In this embodiment, the substrate 100 is a silicon substrate. The single-sided buried strap trench capacitor can be a conventional capacitor known in the art, and formed by any suitable processes. For example, the hardmask 102 is first formed on the substrate 100, and then a trench is formed in the substrate 100. A lower electrode, a capacitor dielectric, an upper electrode, a collar dielectric, a conductor, and a single-sided buried strap are sequentially formed in the trench. In order not to obscure the present invention, only the upper portion of the trench capacitor is illustrated, however, the person skilled in the art should understand that there will be other elements. Therefore, as shown in FIG. 1A and FIG. 1B, four single-sided buried strap trench capacitors are arranged in array as known in the art. The substrate structure includes the substrate 100, the hardmask 102 on the substrate 100, a collar dielectric 104 within the substrate 100, a conductor 106, and a single-sided buried strap 108. The hardmask 102 may include an oxide layer, a nitride layer or a combination thereof. As shown in FIG. 1B, the single-sided buried strap 108 does not fully fill the trench so that the opening 110 is formed.

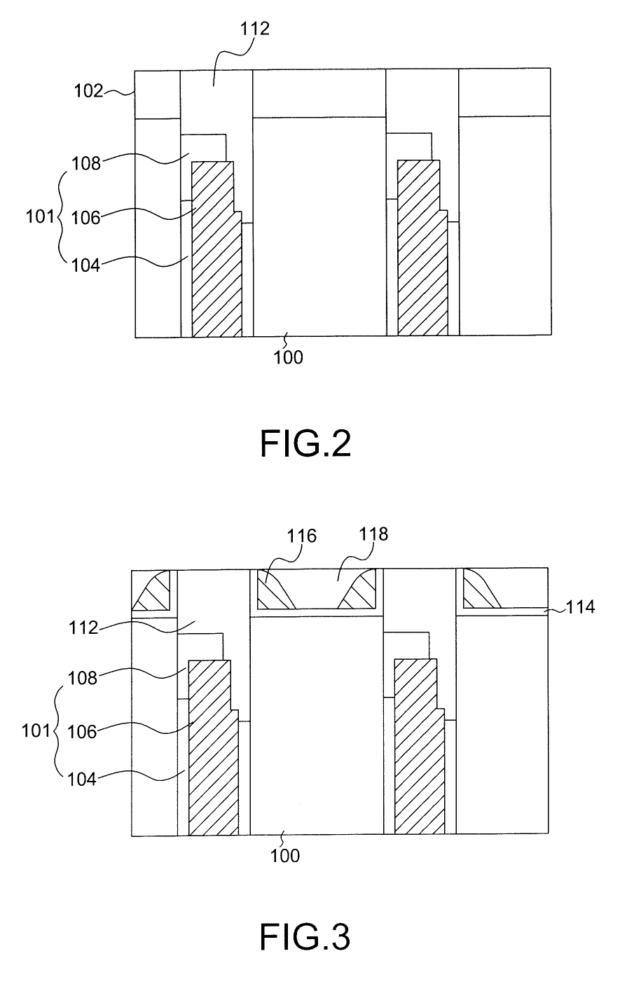

With reference to FIG. 2, after the structure of FIG. 1B is formed, a plug 112 is formed in each of the openings 110 and substantially coplanar with the hardmask 102. For example, a blanket oxide layer is deposited on the entire substrate and then chemical mechanical polished or etched back to expose the hardmask 102. The plug 112 substantially coplanar with the hardmask 102 is accordingly formed. As shown in FIG. 3, since the plug 112 and the hardmask 102 are designed with an etching selectivity, the hardmask 102 may be selectively removed to expose the substrate 100. Then, a dielectric liner 114 is conformally formed on the entire structure. For example, the dielectric liner 114 may be a nitride layer, which is formed on the exposed surface of the substrate 100 and the sidewall and the top of the plug 112. A spacer 116 is then formed on the dielectric liner 114, which is on the sidewall of the plug 112. A filling layer 118 is then formed to fill a space between the spacers 116. For example, the spacer 116 may be formed by conformally forming an oxide layer over the entire structure and then anisotropically etched to remove a portion of the conformal oxide layer so that the oxide layer remaining on the sidewall of the plug 114 (or the dielectric liner 116, if exists) serves as the spacer 116. Please note that the thickness of the spacer 116 is associated with the width of the recessed channel to be formed, i.e. the distance between the two vertical walls of the U shape recessed channel. Therefore, the width of the U shape recessed channel can be adjusted by controlling the thickness of the spacer 116. In an exemplary embodiment, the filling layer 118 may be formed by blanket-depositing a polysilicon layer on the entire structure to fill the space between the spacers 116 and then chemical mechanical polished by using the plug 112 as an etch stop so as to form the filling layer 118, as shown in FIG. 3.

With reference to FIG. 4A and FIG. 4B, a masking layer 120 is formed on the structure of FIG. 3 to define an active area 122. For example, a blanket nitride layer may be formed as the masking layer 120, which is patterned by for example, lithography and etching processes, to define the active area 122 along the B-B direction. As shown in FIG. 4A, a plurality of trench isolations 124 are formed adjacent to two sides of the trench capacitors to define the active area 122. For example, a patterned photoresist layer (not shown) defining a pattern of parallel trench isolations is formed on the masking layer 120. By using the patterned photoresist layer as a mask, the unprotected underlying layers, such as portions of the masking layer 120, the filling layer 118, the plug 112, the trench capacitors 101 including the spacer 116, the single-sided buried strap 108, the conductor 106, the collar dielectric 104, and the substrate 100, are removed. The trench openings can be formed after the patterned photoresist is removed. The trench openings are then filled with a dielectric material, such as silicon dioxide, which is then planarized to expose the masking layer 120 so that the plurality of parallel trench isolations 124 are formed along the direction B-B. As shown in FIG. 4A, every adjacent two trench isolations defines the active area 122. Therefore, the location of the recessed channel 126 to be formed is self-aligned and defined by two trench isolations 124 and the spacer 116 between the two trench isolations 124. That is, the location of the recessed channel 126 to be formed is within the substrate 100 corresponding to the filling layer 118.

With reference to FIG. 5, the masking layer 120 is removed to expose the filling layer 118, the spacer 116, the dielectric liner 114 and the plug 112 between the two trench isolations 124. The exposed filling layer 118 and the underlying dielectric layer 114 and the underlying substrate 100 are then removed to form the recessed channel 126. For example, since the spacer 116 and the trench isolations 124 (e.g. oxide layers) are designed to have an etching selectivity with the filling layer 118 (e.g. polysilicon layer), the filling layer 118 and the underlying dielectric liner 114 and the substrate 100 can be etched to a predetermined depth into the substrate 100 by using the spacer 116 and the trench isolations as a mask. Accordingly, one advantage of the present invention is to define the recessed channel 126 by a self-aligning process so as to eliminate the specific photomask for defining the recessed channel, which is generally adopted in a conventional process, and to reduce the possibility of misalignment with a simplified processing flow.

With reference to FIG. 6, a schematic view of a portion of the recessed channel of FIG. 5 is illustrated. As shown in FIG. 6, after the structure of FIG. 5 is completed, the recessed channel 126 is trimmed for shaping the surface profile of the recessed channel 126 into a three-dimensional profile similar to a fin so as to increase the channel area and in turn, to improve the driving current. For example, the structure of FIG. 5 may be dipped into a chemical solution, such as an acid solution, to reduce the spacer 116 and the trench isolations 124. That is, the reduction of the spacer 116 and the trench isolations 124 enlarges the gap (i.e. the distance) between the recessed channel 126 and the spacer 116 and the trench isolations 124 to facilitate the shaping process of the recessed channel 126. For example, the exposed portion of the substrate 100, which represents the recessed channel 126, is dipped into a chemical solution, such as ammonia solution, so that the vertical portions of the U shape recessed channel 126 is rounded and the bottom of the recessed channel 126, such as the horizontal portion of the U shape recessed channel 126, is also shaped toward the trench isolations 124 to have a tube-like profile. As such, the recessed channel 126 is trimmed to have a rounded channel profile, which is a three-dimensional structure similar to a fin structure, and accordingly, the channel area is increased.

In other words, one advantage of the preset invention is to use the spacer 116 and the trench isolations to self-alignedly define the recessed channel. Another advantage of the present invention is to trim the spacer 116 and the trench isolations 124 to enlarge the distance from the recessed channel 126, and accordingly to improve the feasibility of shaping the recessed channel 126 into a tube-like structure resulting in the increase of driving current.

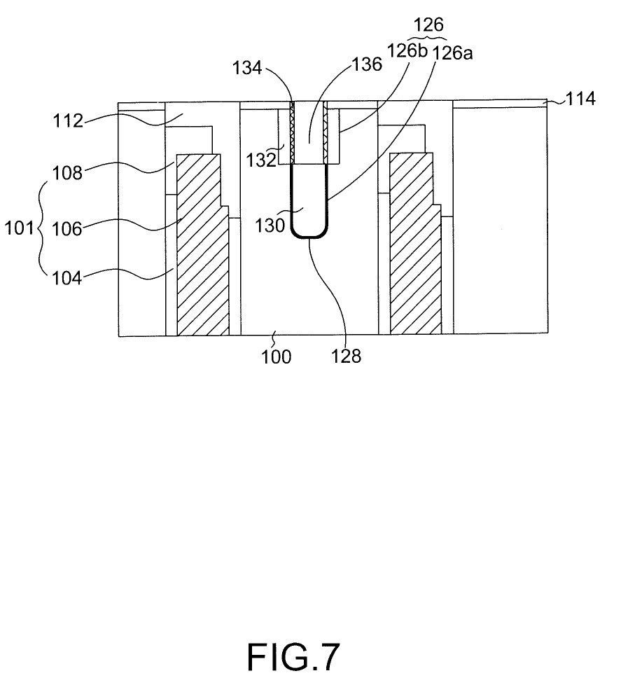

With reference to FIG. 7, after the structure of FIG. 6 is formed, a gate dielectric layer 128, a gate conductor 130, source/drain regions 132, and an isolation 134 may be formed. For example, the gate dielectric layer 128 may be a thermal oxide layer, an oxynitride layer, or a low k dielectric layer, which can be formed by thermal oxidation or atomic layer deposition to cover the recessed channel 126. The, a portion of the gate dielectric 128 is removed to remain the gate dielectric 128 on a lower portion 126a of the recessed channel 126 and to expose an upper portion 126b of the recessed channel 126. The gate conductor 130 is blanket-deposited and etched back so that the gate conductor 130 is formed on the gate dielectric 128 to fill the space defined by the lower portion 126a of the recessed channel 126 and to expose the upper portion 126b of the recessed channel 126. In one exemplary embodiment, the gate conductor 130 may be a polysilicon layer. The source/drain regions 132 can be formed within the substrate 100 adjacent to the upper portion 126b of the recessed channel 126 by a tilted ion implantation process. Followed by thermal oxidation, deposition, or etching processes, the isolation 134 may be formed on the upper portion 126b of the recessed channel 126 and adjacent to the source/drain regions. Then, the plug conductor 136 is formed in the space defined by the upper portion 126b of the recessed channel 126 and adjacent to the isolation 134. The plug conductor 134 is electrically coupled with the gate conductor 130 and isolated from the source/drain regions 132 by the isolation 134. The plug conductor 136 may be formed by blanket-depositing a polysilicon layer to fill the space defined by the upper portion 126b of the recessed channel 126 and chemical mechanical polishing the polysilicon layer to remove the overlying layers above the substrate 100, ash shown in FIG. 7. Please note that the effective channel length of the recessed channel 126 is the lower portion 126a of the recessed channel 126, which is covered by the gate dielectric 128.

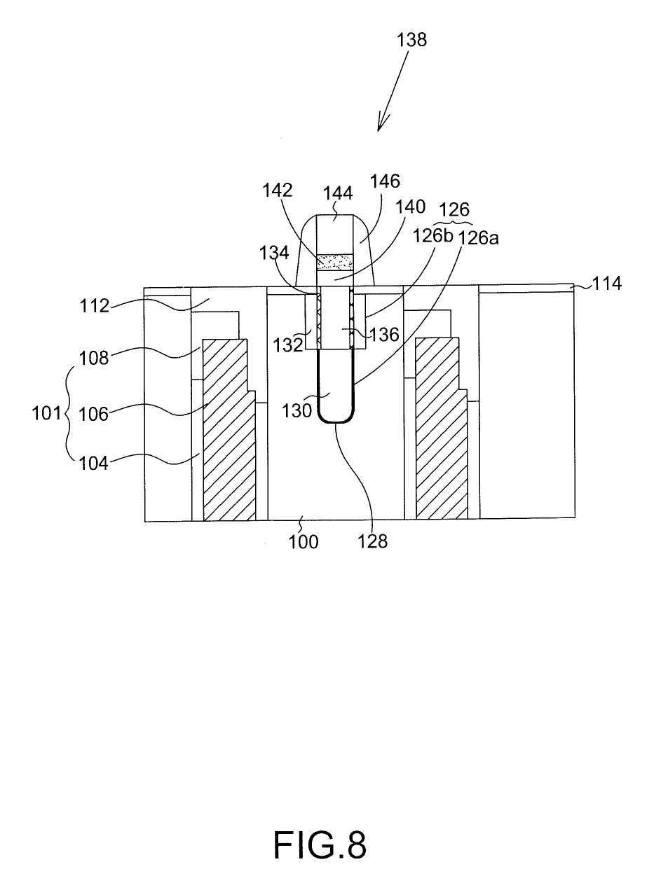

With reference to FIG. 8, a control gate 130 is defined along a direction particular to the B-B direction of FIG. 1A. For example, a second gate conductor 140 is blanket-formed on the plug conductor 136, a metal layer 142 is selectively formed on the second gate conductor 140, and a cap layer 144 is formed on the metal layer 142. The metal layer 142 and the cap layer 144 can be any suitable material known in the art, such as tungsten and nitride, respectively. A patterned photoresist (not shown) is then formed on the cap layer 144 to define the pattern of control gate in the direction perpendicular to the B-B direction. Then, the unprotected portions of the polysilicon layer 140, the metal layer 142, and the cap layer 144 are removed to form the control gate 138 by using the patterned photoresist as a mask. A dielectric spacer 146, such as a nitride layer, is then formed on a sidewall of the control gate 138, as shown in FIG. 8. Subsequently, the processes of forming source/drain contacts, the gate contact, and the wiring can be performed to complete the manufacture of a recessed channel memory device.

In another embodiment, the present invention also provides a recessed channel device as shown in FIG. 4A and FIG. 8, which includes a substrate 100, a plurality of trench capacitors 101 arranged in array within the substrate 100, a plurality of trench isolations 124 along a first direction (i.e. B-B direction) in the substrate 100 and adjacent to the trench capacitors 101 to define an active area 122, and a recessed channel 126 with a rounded channel profile.

The recessed channel 126 further includes a gate dielectric 128 covering the recessed channel 126, a gate conductor 130 on the gate dielectric 128, source/drain regions 132 in the substrate 100 adjacent to the upper portion 126b of the recessed channel 126, an isolation 134 adjacent to the source/drain regions 132, a plug conductor 136 adjacent to the isolation 134 and coupling with the gate conductor 130, and a control gate 138 along a second direction perpendicular to the first direction (i.e. the B-B direction) on the plug conductor 136. The control gate 130 sequentially includes a second gate conductor 140, a metal layer 142, and a cap layer 144 on the gate conductor 136. The recessed channel device further includes a dielectric spacer 146 on the sidewall of the control gate 136.

Please note that though specific materials, such as oxide, nitride, polysilicon, are illustrated for specific layers in the embodiments, the person skilled in the art should appreciate that the present invention can be also achieved by selecting different materials based on the etching selectivity and the characteristic of the materials, and the materials are not limited to those described in the embodiments. That is, the present invention integrates the trench capacitor with self-aligned technique to define the recessed channel with improved channel profile so as to increase the effective channel length and the channel area and in turn to enhance the driving current of the memory device.

The present invention has been described above with reference to preferred embodiments. However, those skilled in the art will understand that the scope of the present invention need not be limited to the disclosed preferred embodiments. On the contrary, it is intended to cover various modifications and equivalent arrangements within the scope defined in the following appended claims. The scope of the claims should be accorded the broadest interpretation so as to encompass all such modifications and equivalent arrangements.

What is claimed is:

1. A method for forming a recessed channel device, the method comprising:
providing a substrate with a plurality of trench capacitors formed therein, each of the trench capacitors comprising a plug protruding above the substrate;
forming a spacer on each of the plugs;
forming a plurality of trench isolations along a first direction in the substrate adjacent to the trench capacitors so as to define an active area exposing the substrate;
removing a portion of the substrate by using the spacers and the trench isolations as a mask to form a recessed channel; and
trimming the recessed channel so that a surface profile of the recessed channel presents a three-dimensional shape.

2. The method for forming a recessed channel device of claim 1, wherein the trench capacitors comprise a single-sided buried strap trench capacitor.

3. The method for forming a recessed channel device of claim 1, prior to the step of forming the spacer further comprising conformally forming a dielectric liner on the substrate.

4. The method for forming a recessed channel device of claim 3, after the step of forming the spacer further comprising forming a filling layer filling between the spacers.

5. The method for forming a recessed channel device of claim 4, wherein the step of forming the filling layer comprises:
blanket-forming a polysilicon layer to fill a space between the spacers; and
chemical mechanical polishing the polysilicon layer to expose the plugs.

6. The method for forming a recessed channel device of claim 5, wherein the step of forming the trench isolations comprises:
using lithography technique to define a pattern of parallel trench isolations on the substrate;
removing portions of the filling layer, the plugs, the trench capacitors, and the substrate to form a plurality of parallel trench openings by using the pattern of parallel trench isolations as a mask; and
filling the trench openings with a dielectric material.

7. The method for forming a recessed channel device of claim 1, wherein the step of trimming the recessed channel comprises:
reducing the spacers and the trench isolations; and
etching a portion of the recessed channel so that the recessed channel has a rounded channel profile.

8. The method for forming a recessed channel device of claim 7, further comprising forming a gate dielectric layer on a lower potion of the recessed channel.

9. The method for forming a recessed channel device of claim 8, further comprising forming a gate conductor on the gate dielectric layer to fill a space defined by the recessed channel.

10. The method for forming a recessed channel device of claim 1, further comprising forming source/drain regions in the substrate adjacent to an upper portion of the recessed channel.

11. The method for forming a recessed channel device of claim 10, further comprising forming an isolation on a sidewall of the upper portion of the recessed channel to isolate the gate conductor and the source/drain regions.

12. The method for forming a recessed channel device of claim 11, further comprising forming a control gate on the gate conductor.

13. The method for forming a recessed channel device of claim 12, wherein the step of forming the control gate comprises sequentially forming a conductor layer, a metal layer, and a cap layer on the gate conductor.

14. The method for forming a recessed channel device of claim 12, further comprising forming a dielectric spacer on the control gate.

15. A recessed channel device, comprising:
a substrate with at least two trench capacitors formed therein; and
a recessed channel in the substrate between the two trench capacitors, wherein the recessed channel has a rounded channel profile.

16. The recessed channel device of claim 15, further comprising a gate dielectric layer covering the recessed channel.

17. The recessed channel device of claim 16, further comprising a gate conductor on the gate dielectric layer to fill a space defined by the recessed channel.

18. The recessed channel device of claim 17, further comprising source/drain regions in the substrate adjacent to an upper portion of the recessed channel.

19. The recessed channel device of claim 18, further comprising an isolation on a sidewall of the upper portion of the recessed channel adjacent to the source/drain regions.

20. The recessed channel device of claim 19, further comprising a control gate on the gate conductor.
